(19) United States
(12) Patent Application Publication
(10) Pub. No.: US 2017/0166690 A1
(43) Pub. Date: Jun. 15, 2017

(54) ADVANCED FLOW REACTOR SYNTHESIS OF SEMICONDUCTING POLYMERS

(71) Applicant: CORNING INCORPORATED, CORNING, NY (US)

(72) Inventors: James Robert MATTHEWS, Painted Post, NY (US); Mingqian HE, Horseheads, NY (US)

(21) Appl. No.: 15/039,173

(22) PCT Filed: Nov. 25, 2014
(86) PCT No.: PCT/US2014/067396

§ 371 Date: May 25, 2016

Related U.S. Application Data
(60) Provisional application No. 61/909,682, filed on Nov. 27, 2013.

(51) Int. Cl. C08G 61/12; H01L 51/00

(52) U.S. Cl. CPC C08G 61/126; H01L 51/0036; H01L 51/0043; C08G 2261/92; C08G 2261/95; C08G 2261/91; C08G 2261/3243; C08G 2261/3241; C08G 2261/3223; C08G 2261/124; C08G 2261/1412; C08G 2261/228; H01L 51/05

(57) ABSTRACT

Synthetic processes for forming highly conjugated semiconducting polymers via the use of microreactor systems, such as microfluidic continuous flow reactors are described herein. The compounds synthesized include conjugated systems incorporating fused thiophenes and, more particularly, fused thiophene-based diketopyrrolopyrrole polymers, which are useful as organic semiconductors and have application in modern electronic devices.

This application claims the benefit of priority to International Application No. PCT/US14/67396 filed Nov. 25, 2014 which claims the benefit of priority to U.S. Application No. 61/909,682 filed Nov. 27, 2013, both applications being incorporated herein by reference.

### FIELD

The following description relates to the synthesis of semiconducting polymers via the use of microreactor systems, including the synthesis of fused thiophenes and, more particularly, fused thiophene-based diketopyrrolopyrrole polymers.

### BACKGROUND

Highly conjugated organic materials, due to their interesting electronic and optoelectronic properties, are being investigated for use in a variety of applications, including organic semiconductors (OSCs), field effect transistors (FETs), thin-film transistors (TFTs), organic light-emitting diodes (OLEDs), electro-optic (EO) applications, as conductive materials, as two photon mixing materials, as organic semiconductors, and as non-linear optical (NLO) materials.

Organic semiconductors (OSCs) have attracted a great amount of attention for next generation electronics due to their interesting electronic and optoelectronic properties and their advantages over inorganic semiconductors, such as processability, high mechanical flexibility, low production costs, and low weight. A number of polycyclic aromatic compounds, such as oligothiophenes, acenes, arylenes, phthalocyanenes, and polythiophenes, have been widely studied as semiconductor materials.

One promising group of compounds for use as OSCs is the fused thiophene-based polymers. These compounds have shown high mobility (up to 5 cm²/V·s) and high on/off ratios (up to 10⁸). However, in order to optimize these properties and the overall quality of the material improved methods of synthesizing the polymers is necessary. The present disclosure cures this unmet need by providing methods of obtaining OSCs with improved yield, higher molecular weights and narrower molecular weight distributions.

### SUMMARY

In the examples described herein, new synthetic methods are described for making fused thiophene-based polymers from fused thiophene-based tin-substituted monomer species. The synthetic methods utilize the advantages of microfluidic technology to provide improved properties for the polymers, which are advantageous in devices incorporating the polymers.

Microfluidic devices, which may be referred to as microstructured reactors, microchannel reactors, microcircuit reactors, or microreactors, (hereinafter, collectively referred to as “microreactors”) are devices in which a fluid can be confined and subjected to processing. Microreactors possessing channels ranging from microns to millimeters, have been designed and used to perform many chemical transformations. The extremely high surface area to volume ratios, high heat transfer, and reduced process volumes associated with microreactors makes them particularly suitable for “process intensification.” Microreactors can be used to assemble flow systems that maximize mass- and heat-transfer and therefore lead to major improvements in the manufacturing of compounds through a decrease in equipment size, energy consumption and waste production all while increasing production capacity. Further, as shown herein, microreactor technology provides polymers with much narrower molecular weight variations via a more precise control of reaction temperature and limiting the number of species a reactant may interact with during the reaction phase.

A first aspect comprises a process comprising the making a compound of formula (I) or formula (II):

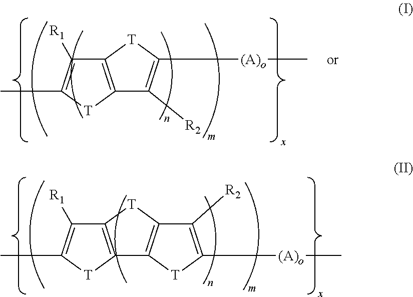

by reacting a compound of formula (Ia) or (IIa):

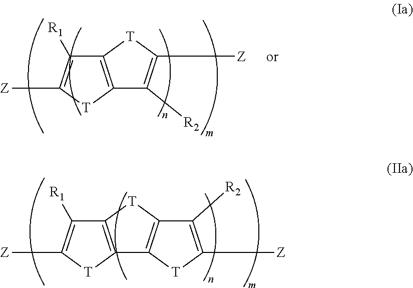

with a compound having the formula:

(R₅)₃Sn-A-Sn(R₅)₃

or by reacting a compound of formula (Ib) or (IIb):

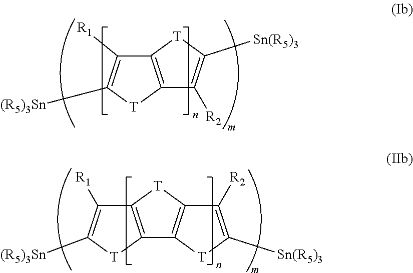

with a compound having the formula:

Z-A-Z

wherein the process is done in a microreactor and with a metal catalyst and wherein each T is independently S, SO, SO₂, Se, Te, BR₃, PR₃, NR₃, CR₃R₄ or SiR₃R₄, each R₃ and R₄ is independently hydrogen, substituted or unsubstituted alkyl, alkoxy, alkylthio, acylamino, acyloxy, aryloxy, substituted or unsubstituted amino, carboxyalkyl, halogen, acyl, substituted or unsubstituted thiol, aralkyl, amino, ester, aldehyde, hydroxyl, thioalkyl, acyl halide, acrylate, carboxy, or vinyl ether, substituted or unsubstituted alkenyl, each R₁ and R₂ are, independently, substituted or unsubstituted alkyl, substituted or unsubstituted alkenyl, substituted or unsubstituted cycloalkyl, substituted or unsubstituted cycloalkenyl, substituted or unsubstituted alkynyl, substituted or unsubstituted aryl, alkoxy, alkylthio, acylamino, acyloxy, aryloxy, substituted or unsubstituted amino, carboxyalkyl, halogen, acyl, substituted or unsubstituted thiol, aralkyl, amino, ester, aldehyde, hydroxyl, thioalkyl, acyl halide, acrylate, carboxy, or vinyl ether, each R₅ is independently substituted or unsubstituted alkyl, each Z is independently Cl, Br, or I, n is an integer of 1 or more, x, m and o are independently integers of 1 or more, and each A is independently a conjugated group. In some embodiments, x is an integer from about 10 to about 200. In some embodiments, o is an integer from 1 to 5, and m is an integer from 1 to 5 and n is an integer of 2 or more. In some cases, A may be selected from the group consisting of an optionally substituted ethylene, butadiene, or acetylene. In some embodiments, A is an optionally substituted aryl. In some embodiments, A may be one selected from the group consisting of optionally substituted benzenes, pyrazoles, naphthalenes, anthracenes, pyrenes, thiophenes, pyrroles, thiozole, porphyrins, carbazoles, furans, indoles, and fused thiophenes.

In some embodiments, the compound made by the processes described herein comprises formula (III) or formula (IV):

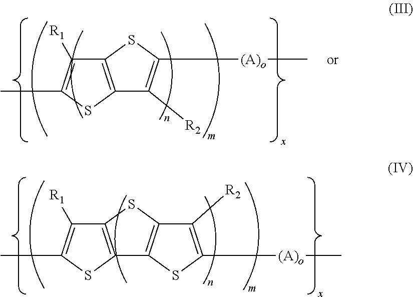

wherein R₁, R₂, n, m, x, and o, are as described above and Ar may be one selected from the group consisting of benzenes, pyrazoles, naphthalenes, anthracenes, pyrenes, thiophenes, pyrroles, thiozole, porphyrins, carbazoles, furans, indoles, and fused thiophenes.

In some embodiments, the compound made by the processes described herein comprises formula (V):

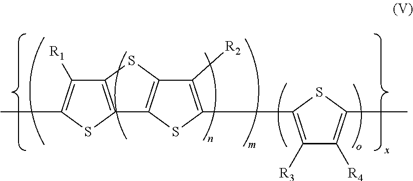

wherein R₁, R₂, n, m, x, and o are as described above.

Another aspect comprises a method of making a compound of formula (VIII) or formula (IX):

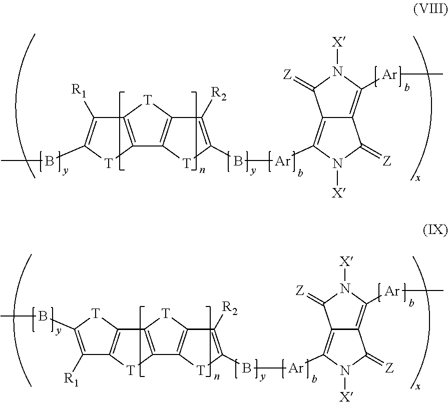

The method may include reacting a compound of formula (Xa) or formula (XIa):

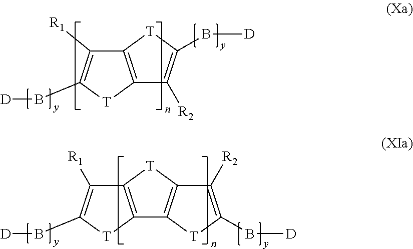

with a compound of formula (XIIa):

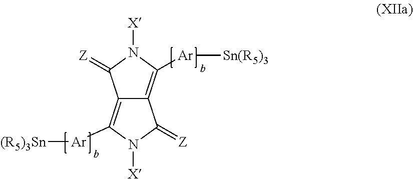

or, alternatively, reacting a compound of formula (Xb) or formula (XIb):

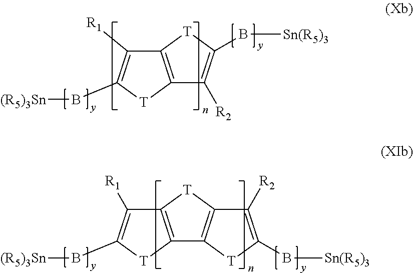

with a compound of formula (XIIb):

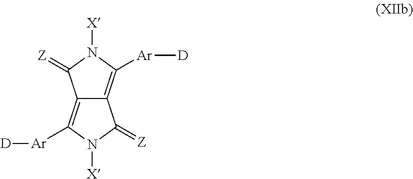

wherein the process is done in a microreactor with a metal catalyst and wherein the process is done in a microreactor with a metal catalyst and wherein each T is independently S, SO, SO₂, Se, Te, BR₃, PR₃, NR₃, CR₃R₄ or SiR₃R₄, each R₃ and R₄ is independently hydrogen, substituted or unsubstituted alkyl, alkoxy, alkylthio, acylamino, acyloxy, aryloxy, substituted or unsubstituted amino, carboxyalkyl, halogen, acyl, substituted or unsubstituted thiol, aralkyl, amino, ester, aldehyde, hydroxyl, thioalkyl, acyl halide, acrylate, carboxy, or vinyl ether, substituted or unsubstituted alkenyl, each R₁ and R₂ are, independently, substituted or unsubstituted alkyl, substituted or unsubstituted alkenyl, substituted or unsubstituted cycloalkyl, substituted or unsubstituted cycloalkenyl, substituted or unsubstituted alkynyl, substituted or unsubstituted aryl, alkoxy, alkylthio, acylamino, acyloxy, aryloxy, substituted or unsubstituted amino, carboxyalkyl, halogen, acyl, substituted or unsubstituted thiol, aralkyl, amino, ester, aldehyde, hydroxyl, thioalkyl, acyl halide, acrylate, carboxy, or vinyl ether, each R₅ is independently substituted or unsubstituted alkyl, each Z may be independently be O, S, Se, or substituted imine, each D may be independently selected from the group consisting of Br, Cl, and I, each y is independently an integer from 0 to 5, each X′ is independently an optionally substituted C₁-C₄₀ linear or branched alkyl or heteroalkyl, or H, b may be independently less than or equal to 5 and greater than or equal to 1, each B and each Ar is independently an optionally substituted conjugated species. In some embodiments, each b may be equal to 1. In some examples, each Z may be independently O, S, or substituted imines. In some embodiments, each Z is oxygen. In some cases, the optionally substituted conjugated species may be one selected from the group consisting of ethylene, butadiene, and acetylene. The optionally substituted aromatic species may be one selected from the group consisting of optionally substituted benzenes, pyrazoles, naphthalenes, anthracenes, pyrenes, thiophenes, pyrroles, thiozole, porphyrins, carbazoles, furans, indoles, and fused thiophenes. Each R and X′ may be independently an optionally substituted C₆-C₂₄ linear alkyl chain. In other embodiments, each R and X′ may be independently an optionally substituted C₁₃-C₁₉ linear alkyl chain. The optionally substituted alkyl chain containing heteroatoms may be one selected from the group consisting of oligo(ethylene glycol), oligo(propylene glycol), and oligo(ethylene diamine). The substituted alkyl chains may include ketone, amine, ester, one or more unsaturations, halide, nitro, aldehyde, hydroxyl, carboxylic acid, alkoxy, or any combination thereof. Each x may independently be an integer from 8 to 250.

In some embodiments of the aspects above, the metal catalyst may be selected from the group consisting of Pt, Pd, Ru, and Rh.

In some embodiments of the aspects described above, the microreactor comprises a continuous-flow microreactor. In other embodiments, the microreactor comprises a microchannel-based microreactor. Additionally, the microreactors may comprise one or more heat exchange channels.

Additional features and advantages of the disclosure are set forth in the detailed description that follows, and in part will be readily apparent to those skilled in the art from that description or recognized by practicing the disclosure as described herein, including the detailed description that follows, the claims, and the appended drawings.

The claims as well as the Abstract are incorporated into and constitute part of the Detailed Description set forth below.

All publications, articles, patents, published patent applications and the like cited herein are incorporated by reference herein in their entirety.

### FIGURES

FIG. 1 is an embodiment of a microreactor as embodied herein.

FIG. 2 shows an example of a microreactor as embodied herein where the microreactor comprises a low-flow reactor as used in the examples.

### DETAILED DESCRIPTION

The claimed invention may be embodied in many different forms and should not be construed as limited to the example embodiments set forth herein. These example embodiments are provided so that this disclosure will be both thorough and complete, and will fully convey the scope of the claimed invention to those skilled in the art.

Before the present materials, articles, and/or methods are disclosed and described, it is to be understood that the aspects described below are not limited to specific compounds, synthetic methods, or uses as such may, of course, vary. It is also to be understood that the terminology used herein is for the purpose of describing particular aspects only and is not intended to be limiting.

In this specification and in the claims that follow, reference will be made to a number of terms that shall be defined to have the following meanings:

Throughout this specification, unless the context requires otherwise, the word “comprise,” or variations such as “comprises” or “comprising,” will be understood to imply the inclusion of a stated integer or step or group of integers or steps but not the exclusion of any other integer or step or group of integers or steps.

It must be noted that, as used in the specification and the appended claims, the singular forms “a,” “an” and “the” include plural referents unless the context clearly dictates otherwise. Thus, for example, reference to “a fused thiophene” includes mixtures of two or more such fused thiophenes, and the like.

“Optional” or “optionally” means that the subsequently described event or circumstance can or cannot occur, and that the description includes instances where the event or circumstance occurs and instances where it does not.

Ranges may be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

The term “alkyl” refers to a monoradical branched or unbranched saturated hydrocarbon chain having a variable amount of carbon atoms, typically 1 to 40. This term is exemplified by groups such as methyl, ethyl, n-propyl, iso-propyl, n-butyl, iso-butyl, t-butyl, n-hexyl, n-decyl, tetradecyl, and the like. The term “alkyl” as defined herein, unless otherwise noted, also includes cycloalkyl groups.

The term “cycloalkyl” as used herein is a non-aromatic carbon-based ring composed of at least three carbon atoms, and in some embodiments from 3 to 20 carbon atoms. Examples of cycloalkyl groups include, but are not limited to, cyclopropyl, cyclobutyl, cyclopentyl, cyclohexyl, etc. The term cycloalkyl group also includes a heterocycloalkyl group, where at least one of the carbon atoms of the ring is substituted with a heteroatom such as, but not limited to, nitrogen, oxygen, sulphur, or phosphorus.

The term “substituted alkyl” refers to: (1) an alkyl group as defined above, having 1, 2, 3, 4 or 5 substituents, typically 1 to 3 substituents, selected from the group consisting of alkenyl, alkynyl, alkoxy, cycloalkyl, cycloalkenyl, acyl, acylamino, acyloxy, amino, aminocarbonyl, alkoxycarbonylamino, azido, cyano, halogen, hydroxy, keto, thiocarbonyl, carboxy, carboxyalkyl, arylthio, heteroarylthio, heterocyclothio, thiol, alkylthio, aryl, aryloxy, heteroaryl, aminosulfonyl, aminocarbonylamino, heteroaryloxy, heterocyclic, heterocyclooxy, hydroxyamino, alkoxyamino, nitro, —SO-alkyl, —SO-aryl, —SO-heteroaryl, —SO₂-alkyl, SO₂-aryl and —SO₂-heteroaryl. Unless otherwise constrained by the definition, all substituents may optionally be further substituted by 1, 2, or 3 substituents chosen from alkyl, carboxy, carboxyalkyl, aminocarbonyl, hydroxy, alkoxy, halogen, CF₃, amino, substituted amino, cyano, and —S(O)ₚR_{SO}, where R_{SO} is alkyl, aryl, or heteroaryl and p is 0, 1 or 2; or (2) an alkyl group as defined above that is interrupted by 1-10 atoms independently chosen from oxygen, sulfur and NRₐ, where Rₐ is chosen from hydrogen, alkyl, cycloalkyl, alkenyl, cycloalkenyl, alkynyl, aryl, heteroaryl and heterocyclic. All substituents may be optionally further substituted by alkyl, alkoxy, halogen, CF₃, amino, substituted amino, cyano, or —S(O)ₚR_{SO}, in which R_{SO} is alkyl, aryl, or heteroaryl and p is 0, 1 or 2; or (3) an alkyl group as defined above that has both 1, 2, 3, 4 or 5 substituents as defined above and is also interrupted by 1-10 atoms as defined above.

The term “alkoxy” refers to the group D-O—, where D is an optionally substituted alkyl or optionally substituted cycloalkyl, or D is a group —Y—W, in which Y is optionally substituted alkylene and W is optionally substituted alkenyl, optionally substituted alkynyl; or optionally substituted cycloalkenyl, where alkyl, alkenyl, alkynyl, cycloalkyl and cycloalkenyl are as defined herein. Typical alkoxy groups are optionally substituted alkyl-O— and include, by way of example, methoxy, ethoxy, n-propoxy, iso-propoxy, n-butoxy, tert-butoxy, sec-butoxy, n-pentoxy, n-hexoxy, 1,2-dimethylbutoxy, trifluoromethoxy, and the like.

The term “alkylene” refers to a diradical of a branched or unbranched saturated hydrocarbon chain, having 1, 2, 3, 4, 5, 6, 7, 8, 9, 10, 11, 12, 13, 14, 15, 16, 17, 18, 19 or 20 carbon atoms, typically 1-10 carbon atoms, more typically 1, 2, 3, 4, 5 or 6 carbon atoms. This term is exemplified by groups such as methylene (—CH₂—), ethylene (—CH₂CH₂—), the propylene isomers (e.g., —CH₂CH₂CH₂— and —CH(CH₃)CH₂—) and the like.

The term “substituted alkylene” refers to: (1) an alkylene group as defined above having 1, 2, 3, 4, or 5 substituents selected from the group consisting of alkyl, alkenyl, alkynyl, alkoxy, cycloalkyl, cycloalkenyl, acyl, acylamino, acyloxy, amino, aminocarbonyl, alkoxycarbonylamino, azido, cyano, halogen, hydroxy, keto, thiocarbonyl, carboxy, carboxyalkyl, arylthio, heteroarylthio, heterocyclothio, thiol, alkylthio, aryl, aryloxy, heteroaryl, aminosulfonyl, aminocarbonylamino, heteroaryloxy, heterocyclic, heterocyclooxy, hydroxyamino, alkoxyamino, nitro, —SO-alkyl, —SO-aryl, —SO-heteroaryl, —SO₂-alkyl, —SO₂-aryl and —SO₂-heteroaryl. Unless otherwise constrained by the definition, all substituents may optionally be further substituted by 1, 2, or 3 substituents chosen from alkyl, carboxy, carboxyalkyl, aminocarbonyl, hydroxy, alkoxy, halogen, CF₃, amino, substituted amino, cyano, and —S(O)ₚR_{SO}, where R_{SO} is alkyl, aryl, or heteroaryl and p is 0, 1 or 2; or (2) an alkylene group as defined above that is interrupted by 1-20 atoms independently chosen from oxygen, sulfur and NRₐ—, where Rₐ is chosen from hydrogen, optionally substituted alkyl, cycloalkyl, cycloalkenyl, aryl, heteroaryl and heterocyclic, or groups selected from carbonyl, carboxyester, carboxyamide and sulfonyl; or (3) an alkylene group as defined above that has both 1, 2, 3, 4 or 5 substituents as defined above and is also interrupted by 1-20 atoms as defined above. Examples of substituted alkylenes are chloromethylene (—CH(Cl)—), aminoethylene (—CH(NH₂)CH₂—), methylaminoethylene (—CH(NHMe)CH₂—), 2-carboxypropylene isomers (—CH₂CH(CO₂H)CH₂—), ethoxyethyl (—CH₂CH₂O—CH₂CH₂—), ethylmethylaminoethyl (—CH₂CH₂N(CH₃)CH₂CH₂—), and the like.

The term “alkylthio” refers to the group R_{S}—S—, where R_{S} is defined as an optionally substituted alkyl or optionally substituted cycloalkyl, or D is a group —Y—W, in which Y is optionally substituted alkylene and W is optionally substituted alkenyl, optionally substituted alkynyl; or optionally substituted cycloalkenyl, where alkyl, alkenyl, alkynyl, cycloalkyl and cycloalkenyl are as defined herein.

The term “alkenyl” refers to a monoradical of a branched or unbranched unsaturated hydrocarbon group typically having from 2 to 30 carbon atoms, more typically 2 to 10 carbon atoms and even more typically 2 to 6 carbon atoms and having 1-6, typically 1, double bond (vinyl). Typical alkenyl groups include ethenyl or vinyl (—CH═CH₂), 1-propylene or allyl (—CH₂CH═CH₂), isopropylene (—C(CH₃)═CH₂), bicyclo[2.2.1]heptene, and the like. In the event that alkenyl is attached to nitrogen, the double bond cannot be alpha to the nitrogen. The term “alkenyl” as defined herein, unless otherwise noted, also includes cycloalkenyl groups.

The term “substituted alkenyl” refers to an alkenyl group as defined above having 1, 2, 3, 4 or 5 substituents, and typically 1, 2, or 3 substituents, selected from the group consisting of alkyl, alkenyl, alkynyl, alkoxy, cycloalkyl, cycloalkenyl, acyl, acylamino, acyloxy, amino, aminocarbonyl, alkoxycarbonylamino, azido, cyano, halogen, hydroxy, keto, thiocarbonyl, carboxy, carboxyalkyl, arylthio, heteroarylthio, heterocyclothio, thiol, alkylthio, aryl, aryloxy, heteroaryl, aminosulfonyl, aminocarbonylamino, heteroaryloxy, heterocyclic, heterocyclooxy, hydroxyamino, alkoxyamino, nitro, —SO— alkyl, —SO-aryl, —SO-heteroaryl, —SO₂-alkyl, —SO₂-aryl and —SO₂-heteroaryl. Unless otherwise constrained by the definition, all substituents may optionally be further substituted by 1, 2, or 3 substituents chosen from alkyl, carboxy, carboxyalkyl, aminocarbonyl, hydroxy, alkoxy, halogen, CF₃, amino, substituted amino, cyano, and —S(O)ₚR_{SO}, where R_{SO} is alkyl, aryl, or heteroaryl and p is 0, 1 or 2.

The term “alkynyl” refers to a monoradical of an unsaturated hydrocarbon, typically having from 2 to 20 carbon atoms, more typically 2 to 10 carbon atoms and even more typically 2 to 6 carbon atoms and having at least 1 and typically from 1-6 sites of acetylene (triple bond) unsaturation. Typical alkynyl groups include ethynyl, (—C≡CH), propargyl (or prop-1-yn-3-yl, —CH₂C≡CH), and the like. In the event that alkynyl is attached to nitrogen, the triple bond cannot be alpha to the nitrogen. The term “alkynyl” as defined herein, unless otherwise noted, also includes cycloalkynyl groups.

The term “substituted alkynyl” refers to an alkynyl group as defined above having 1, 2, 3, 4 or 5 substituents, and typically 1, 2, or 3 substituents, selected from the group consisting of alkyl, alkenyl, alkynyl, alkoxy, cycloalkyl, cycloalkenyl, acyl, acylamino, acyloxy, amino, aminocarbonyl, alkoxycarbonylamino, azido, cyano, halogen, hydroxy, keto, thiocarbonyl, carboxy, carboxyalkyl, arylthio, heteroarylthio, heterocyclothio, thiol, alkylthio, aryl, aryloxy, heteroaryl, aminosulfonyl, aminocarbonylamino, heteroaryloxy, heterocyclic, heterocyclooxy, hydroxyamino, alkoxyamino, nitro, —SO-alkyl, —SO-aryl, —SO-heteroaryl, —SO₂-alkyl, —SO₂-aryl and —SO₂-heteroaryl. Unless otherwise constrained by the definition, all substituents may optionally be further substituted by 1, 2, or 3 substituents chosen from alkyl, carboxy, carboxyalkyl, aminocarbonyl, hydroxy, alkoxy, halogen, CF₃, amino, substituted amino, cyano, and —S(O)ₚR_{SO}, where R_{SO} is alkyl, aryl, or heteroaryl and p is 0, 1 or 2.

The term “aminocarbonyl” refers to the group —C(O)NR_{N}R_{N} where each R_{N} is independently hydrogen, alkyl, aryl, heteroaryl, heterocyclic or where both R_{N} groups are joined to form a heterocyclic group (e.g., morpholino). Unless otherwise constrained by the definition, all substituents may optionally be further substituted by 1-3 substituents chosen from alkyl, carboxy, carboxyalkyl, aminocarbonyl, hydroxy, alkoxy, halogen, CF₃, amino, substituted amino, cyano, and —S(O)ₚR_{SO}, where R_{SO} is alkyl, aryl, or heteroaryl and p is 0, 1 or 2.

The term “acylamino” refers to the group —NR_{NCO}C(O)R where each R_{NCO} is independently hydrogen, alkyl, aryl, heteroaryl, or heterocyclic. Unless otherwise constrained by the definition, all substituents may optionally be further substituted by 1-3 substituents chosen from alkyl, carboxy, carboxyalkyl, aminocarbonyl, hydroxy, alkoxy, halogen, CF₃, amino, substituted amino, cyano, and —S(O)ₚR_{SO}, where R_{SO} is alkyl, aryl, or heteroaryl and p is 0, 1 or 2.

The term “acyloxy” refers to the groups —O(O)C-alkyl, —O(O)C-cycloalkyl, —O(O)C-aryl, —O(O)C-heteroaryl, and —O(O)C-heterocyclic. Unless otherwise constrained by the definition, all substituents may be optionally further substituted by alkyl, carboxy, carboxyalkyl, aminocarbonyl, hydroxy, alkoxy, halogen, CF₃, amino, substituted amino, cyano, and —S(O)ₚR_{SO}, where R_{SO} is alkyl, aryl, or heteroaryl and p is 0, 1 or 2.

The term “aryl” refers to an aromatic carbocyclic group of 6 to 20 carbon atoms having a single ring (e.g., phenyl) or multiple rings (e.g., biphenyl), or multiple condensed (fused) rings (e.g., naphthyl or anthryl). Typical aryls include phenyl, naphthyl and the like.

Unless otherwise constrained by the definition for the aryl substituent, such aryl groups can optionally be substituted with from 1 to 5 substituents, typically 1 to 3 substituents, selected from the group consisting of alkyl, alkenyl, alkynyl, alkoxy, cycloalkyl, cycloalkenyl, acyl, acylamino, acyloxy, amino, aminocarbonyl, alkoxycarbonylamino, azido, cyano, halogen, hydroxy, keto, thiocarbonyl, carboxy, carboxyalkyl, arylthio, heteroarylthio, heterocyclothio, thiol, alkylthio, aryl, aryloxy, heteroaryl, amino sulfonyl, aminocarbonyl amino, heteroaryloxy, heterocyclic, heterocyclooxy, hydroxyamino, alkoxyamino, nitro, —SO— alkyl, —SO-aryl, —SO— heteroaryl, —SO₂-alkyl, —SO₂-aryl and —SO₂-heteroaryl. Unless otherwise constrained by the definition, all substituents may optionally be further substituted by 1-3 substituents chosen from alkyl, carboxy, carboxyalkyl, aminocarbonyl, hydroxy, alkoxy, halogen, CF₃, amino, substituted amino, cyano, and —S(O)ₚR_{SO}, where R_{SO} is alkyl, aryl, or heteroaryl and p is 0, 1 or 2.

The term “aryloxy” refers to the group aryl-O— wherein the aryl group is as defined above, and includes optionally substituted aryl groups as also defined above. The term “arylthio” refers to the group aryl-S—, where aryl is as defined as above.

The term “amino” refers to the group —NH₂.

The term “substituted amino” refers to the group —NR_{w}R_{w} where each R_{w} is independently selected from the group consisting of hydrogen, alkyl, cycloalkyl, carboxyalkyl (for example, benzyloxycarbonyl), aryl, heteroaryl and heterocyclic provided that both R_{w} groups are not hydrogen, or a group —Y—Z, in which Y is optionally substituted alkylene and Z is alkenyl, cycloalkenyl, or alkynyl. Unless otherwise constrained by the definition, all substituents may optionally be further substituted by 1-3 substituents chosen from alkyl, carboxy, carboxyalkyl, aminocarbonyl, hydroxy, alkoxy, halogen, CF₃, amino, substituted amino, cyano, and —S(O)ₚR_{SO}, where R_{SO} is alkyl, aryl, or heteroaryl and p is 0, 1 or 2.

The term “carboxyalkyl” refers to the groups —C(O)O-alkyl or —C(O)O-cycloalkyl, where alkyl and cycloalkyl, are as defined herein, and may be optionally further substituted by alkyl, alkenyl, alkynyl, alkoxy, halogen, CF₃, amino, substituted amino, cyano, and —S(O)ₚR_{SO}, in which R_{SO} is alkyl, aryl, or heteroaryl and p is 0, 1 or 2.

The term “cycloalkyl” refers to carbocyclic groups of from 3 to 20 carbon atoms having a single cyclic ring or multiple condensed rings. Such cycloalkyl groups include, by way of example, single ring structures such as cyclopropyl, cyclobutyl, cyclopentyl, cyclooctyl, and the like, or multiple ring structures such as adamantanyl, bicyclo[2.2.1]heptane, 1,3,3-trimethylbicyclo[2.2.1]hept-2-yl, (2,3,3-trimethylbicyclo[2.2.1]hept-2-yl), or carbocyclic groups to which is fused an aryl group, for example indane, and the like.

The term “cycloalkenyl” refers to carbocyclic groups of from 3 to 20 carbon atoms having a single cyclic ring or multiple condensed rings with at least one double bond in the ring structure.

The terms “substituted cycloalkyl” or “substituted cycloalkenyl” refer to cycloalkyl or cycloalkenyl groups having 1, 2, 3, 4 or 5 substituents, and typically 1, 2, or 3 substituents, selected from the group consisting of alkyl, alkenyl, alkynyl, alkoxy, cycloalkyl, cycloalkenyl, acyl, acylamino, acyloxy, amino, aminocarbonyl, alkoxycarbonylamino, azido, cyano, halogen, hydroxy, keto, thiocarbonyl, carboxy, carboxyalkyl, arylthio, heteroarylthio, heterocyclothio, thiol, alkylthio, aryl, aryloxy, heteroaryl, aminosulfonyl, aminocarbonylamino, heteroaryloxy, heterocyclic, heterocyclooxy, hydroxyamino, alkoxyamino, nitro, —SO-alkyl, —SO-aryl, —SO— heteroaryl, —SO₂-alkyl, —SO₂-aryl and —SO₂-heteroaryl. Unless otherwise constrained by the definition, all substituents may optionally be further substituted by 1, 2, or 3 substituents chosen from alkyl, carboxy, carboxyalkyl, aminocarbonyl, hydroxy, alkoxy, halogen, CF₃, amino, substituted amino, cyano, and —S(O)ₚR_{SO}, where R_{SO} is alkyl, aryl, or heteroaryl and p is 0, 1 or 2.

The term “halogen” or “halo” refers to fluoro, bromo, chloro, and iodo.

The term “acyl” denotes a group —C(O)R_{CO}, in which R_{CO} is hydrogen, optionally substituted alkyl, optionally substituted cycloalkyl, optionally substituted heterocyclic, optionally substituted aryl, and optionally substituted heteroaryl.

The term “heteroaryl” refers to a radical derived from an aromatic cyclic group (i.e., fully unsaturated) having 1, 2, 3, 4, 5, 6, 7, 8, 9, 10, 11, 12, 13, 14, or 15 carbon atoms and 1, 2, 3 or 4 heteroatoms selected from oxygen, nitrogen and sulfur within at least one ring. Such heteroaryl groups can have a single ring (e.g., pyridyl or furyl) or multiple condensed rings (e.g., indolizinyl, benzothiazolyl, or benzothienyl). Examples of heteroaryls include, but are not limited to, [1,2,4]oxadiazole, [1,3,4]oxadiazole, [1,2,4]thiadiazole, [1,3,4]thiadiazole, pyrrole, imidazole, pyrazole, pyridine, pyrazine, pyrimidine, pyridazine, indolizine, isoindole, indole, indazole, purine, quinolizine, isoquinoline, quinoline, phthalazine, naphthylpyridine, quinoxaline, quinazoline, cinnoline, pteridine, carbazole, carboline, phenanthridine, acridine, phenanthroline, isothiazole, phenazine, isoxazole, phenoxazine, phenothiazine, imidazolidine, imidazoline, triazole, oxazole, thiazole, naphthyridine, and the like as well as N-oxide and N-alkoxy derivatives of nitrogen containing heteroaryl compounds, for example pyridine-N-oxide derivatives.

Unless otherwise constrained by the definition for the heteroaryl substituent, such heteroaryl groups can be optionally substituted with 1 to 5 substituents, typically 1 to 3 substituents selected from the group consisting of alkyl, alkenyl, alkynyl, alkoxy, cycloalkyl, cycloalkenyl, acyl, acylamino, acyloxy, amino, aminocarbonyl, alkoxycarbonylamino, azido, cyano, halogen, hydroxy, keto, thiocarbonyl, carboxy, carboxyalkyl, arylthio, heteroarylthio, heterocyclothio, thiol, alkylthio, aryl, aryloxy, heteroaryl, aminosulfonyl, aminocarbonyl amino, heteroaryloxy, heterocyclic, heterocyclooxy, hydroxyamino, alkoxyamino, nitro, —SO— alkyl, —SO-aryl, —SO— heteroaryl, —SO₂-alkyl, —SO₂-aryl and —SO₂-heteroaryl. Unless otherwise constrained by the definition, all substituents may optionally be further substituted by 1-3 substituents chosen from alkyl, carboxy, carboxyalkyl, aminocarbonyl, hydroxy, alkoxy, halogen, CF₃, amino, substituted amino, cyano, and —S(O)ₚR_{SO}, where R_{SO} is alkyl, aryl, or heteroaryl and p is 0, 1 or 2.

The term “heteroaryloxy” refers to the group heteroaryl-O—.

The term “heterocyclic” refers to a monoradical saturated or partially unsaturated group having a single ring or multiple condensed rings, having from 1 to 40 carbon atoms and from 1 to 10 hetero atoms, typically 1, 2, 3 or 4 heteroatoms, selected from nitrogen, sulfur, phosphorus, and/or oxygen within the ring. Heterocyclic groups can have a single ring or multiple condensed rings, and include tetrahydrofuranyl, morpholino, piperidinyl, piperazino, dihydropyridino, and the like.

Unless otherwise constrained by the definition for the heterocyclic substituent, such heterocyclic groups can be optionally substituted with 1, 2, 3, 4 or 5, and typically 1, 2 or 3 substituents, selected from the group consisting of alkyl, alkenyl, alkynyl, alkoxy, cycloalkyl, cycloalkenyl, acyl, acylamino, acyloxy, amino, aminocarbonyl, alkoxycarbonylamino, azido, cyano, halogen, hydroxy, keto, thiocarbonyl, carboxy, carboxyalkyl, arylthio, heteroarylthio, heterocyclothio, thiol, alkylthio, aryl, aryloxy, heteroaryl, aminosulfonyl, aminocarbonylamino, heteroaryloxy, heterocyclic, heterocyclooxy, hydroxyamino, alkoxyamino, nitro, —SO— alkyl, —SO-aryl, —SO— heteroaryl, —SO₂-alkyl, —SO₂-aryl and —SO₂-heteroaryl. Unless otherwise constrained by the definition, all substituents may optionally be further substituted by 1-3 substituents chosen from alkyl, carboxy, carboxyalkyl, aminocarbonyl, hydroxy, alkoxy, halogen, CF₃, amino, substituted amino, cyano, and —S(O)ₚR_{SO}, where R_{SO} is alkyl, aryl, or heteroaryl and p is 0, 1 or 2.

The term “thiol” refers to the group —SH.

The term “alkylthio” refers to the group —S— optionally substituted alkyl.

The term “heteroarylthio” refers to the group —S— heteroaryl wherein the heteroaryl group is as defined above including optionally substituted heteroaryl groups as also defined above.

The term “sulfoxide” refers to a group —S(O)R_{SO}, in which R_{SO} is an optionally substituted alkyl, aryl, or heteroaryl.

The term “sulfone” refers to a group —S(O)₂R_{SO}, in which R_{SO} is an optionally substituted alkyl, aryl, or heteroaryl.

The term “keto” refers to a group —C(O)—.

The term “thiocarbonyl” refers to a group —C(S)—.

The term “carboxy” refers to a group —C(O)OH.

The term “conjugated group” or “conjugated species” is defined as a linear, branched or cyclic group, or combination thereof, in which p-orbitals of the atoms within the group are connected via delocalization of electrons and wherein the structure can be described as containing alternating single and double or triple bonds and may further contain lone pairs, radicals, or carbenium ions. Conjugated cyclic groups may comprise both aromatic and non-aromatic groups, and may comprise polycyclic or heterocyclic groups, such as diketopyrrolopyrrole. Ideally, conjugated groups are bound in such a way as to continue the conjugation between the moieties they connect.

Disclosed are compounds, compositions, and components that can be used for, can be used in conjunction with, can be used in preparation for, or are products of the disclosed methods and compositions. These and other materials are disclosed herein, and it is understood that when combinations, subsets, interactions, groups, etc. of these materials are disclosed that while specific reference of each various individual and collective combinations and permutation of these compounds may not be explicitly disclosed, each is specifically contemplated and described herein. Thus, if a class of molecules A, B, and C are disclosed as well as a class of molecules D, E, and F and an example of a combination molecule, A-D is disclosed, then even if each is not individually recited, each is individually and collectively contemplated. Thus, in this example, each of the combinations A-E, A-F, B-D, B-E, B-F, C-D, C-E, and C-F are specifically contemplated and should be considered disclosed from disclosure of A, B, and C; D, E, and F; and the example combination A-D. Likewise, any subset or combination of these is also specifically contemplated and disclosed. Thus, for example, the sub-group of A-E, B-F, and C-E are specifically contemplated and should be considered disclosed from disclosure of A, B, and C; D, E, and F; and the example combination A-D. This concept applies to all aspects of this disclosure including, but not limited to, steps in methods of making and using the disclosed compositions. Thus, if there are a variety of additional steps that can be performed it is understood that each of these additional steps can be performed with any specific embodiment or combination of embodiments of the disclosed methods, and that each such combination is specifically contemplated and should be considered disclosed.

In the examples described herein, new synthetic methods are described for making fused thiophene-based polymers from fused thiophene-based tin-substituted monomer species. The synthetic methods utilize the advantages of microreactor technology to provide improved properties for the polymers, which are advantageous in devices incorporating the polymers.

Generally described herein are processes comprising the synthesis of a compound of formula (I) or formula (II):

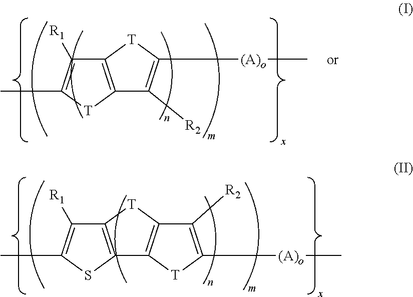

by reacting a compound of formula (Ia) or (IIa):

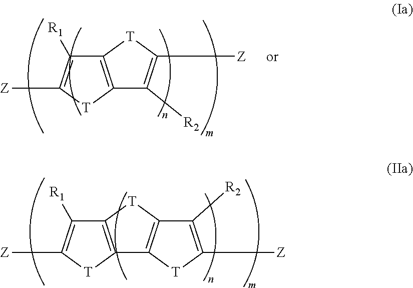

with a compound having the formula:

(R₅)₃Sn-A-Sn(R₅)₃

Or, alternatively, by reacting a compound of formula (Ib) or (IIb):

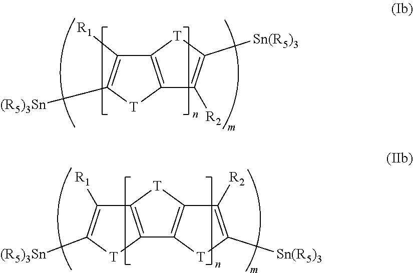

with a compound having the formula:

Z-A-Z

wherein the process is done in a microreactor and with a metal catalyst. As used in this embodiment, each T is independently S, SO, SO₂, Se, Te, BR₃, PR₃, NR₃, CR₃R₄ or SiR₃R₄, each R₃ and R₄ is independently hydrogen, substituted or unsubstituted alkyl, alkoxy, alkylthio, acylamino, acyloxy, aryloxy, substituted or unsubstituted amino, carboxyalkyl, halogen, acyl, substituted or unsubstituted thiol, aralkyl, amino, ester, aldehyde, hydroxyl, thioalkyl, acyl halide, acrylate, carboxy, or vinyl ether, substituted or unsubstituted alkenyl, each R₁ and R₂ are, independently, substituted or unsubstituted alkyl, substituted or unsubstituted alkenyl, substituted or unsubstituted cycloalkyl, substituted or unsubstituted cycloalkenyl, substituted or unsubstituted alkynyl, substituted or unsubstituted aryl, alkoxy, alkylthio, acylamino, acyloxy, aryloxy, substituted or unsubstituted amino, carboxyalkyl, halogen, acyl, substituted or unsubstituted thiol, aralkyl, amino, ester, aldehyde, hydroxyl, thioalkyl, acyl halide, acrylate, carboxy, or vinyl ether, each R₅ is independently substituted or unsubstituted alkyl, each Z is independently Cl, Br, or I, n is an integer of 1 or more, x, m and o are independently integers of 1 or more, and each A is independently a conjugated group. In some embodiments, x is an integer from about 10 to about 200. In some embodiments, o is an integer from 1 to 5, and m is an integer from 1 to 5, and n is an integer of 2 or more. In some cases, A may be selected from the group consisting of an optionally substituted ethylene, butadiene, or acetylene. In some embodiments, A is an optionally substituted aryl. In some embodiments, A may be one selected from the group consisting of optionally substituted benzenes, pyrazoles, naphthalenes, anthracenes, pyrenes, thiophenes, pyrroles, thiozoles, porphyrins, carbazoles, furans, indoles, and fused thiophenes.

The reaction described above is advantageously run in a microreactor. Microreactors, as used herein, and more particularly glass, glass-ceramic and ceramic microfluidic devices (generally referred to as microstructures), are described in numerous patents and applications, for example in U.S. Pat. Nos. 7,007,709, 8,043,571, Ser. Nos. 13/266,350, 13/318,496, FR 2 821 657, WO 2005/107 937, EP 1 925 364, and US 2007/280855. The use of a microreactor flow system with good thermal control and relatively fast heat and mass transfer allows for the polymerization reactions to be run with greater heat and reaction control. The short residence times thus achievable result in high throughput and the small reaction vessels provide for less molecular weight variation. In the process, one or more working fluids confined in the microfluidic device may exchange heat with one or more associated heat exchange fluids. In any case, the characteristic smallest dimensions of the confined spaces for the working fluids are generally on the order of 0.1 mm to 5 mm, desirably 0.5 mm to 2 mm.

In some cases, the microreactor comprises microchannels. Microreactors that employ microchannels offer many advantages over conventional-scale reactors, including vast improvements in energy efficiency, reaction speed, reaction yield, safety, reliability, scalability, etc. The use of a microchannel-based device also allows the microreactor to operate as a continuous-flow reactor. The internal dimensions of the microchannels provide considerable improvement in mass and heat transfer rates. According to one embodiment of the present disclosure, a microchannel microreactor is provided. The microchannel microreactor comprises a microchannel housing comprising a plurality of channels positioned for flow (gravity, pressure, pump-assisted, etc.) and an upper microstructure disposed above the microchannel housing. The upper microstructure comprises one or more liquid feed circuits and at least one mixing cavity. The microchannel housing comprises at least one reactive passage, and the mixing cavity is in fluid communication with the reactive passage. The feed circuits each comprise at least one liquid feed inlet and at least one liquid reservoir adjacent to the mixing cavity, wherein the liquid feed is in fluid communication with the at least one liquid feed inlet. The liquid reservoir is operable to deliver a liquid feed into the mixing cavity.

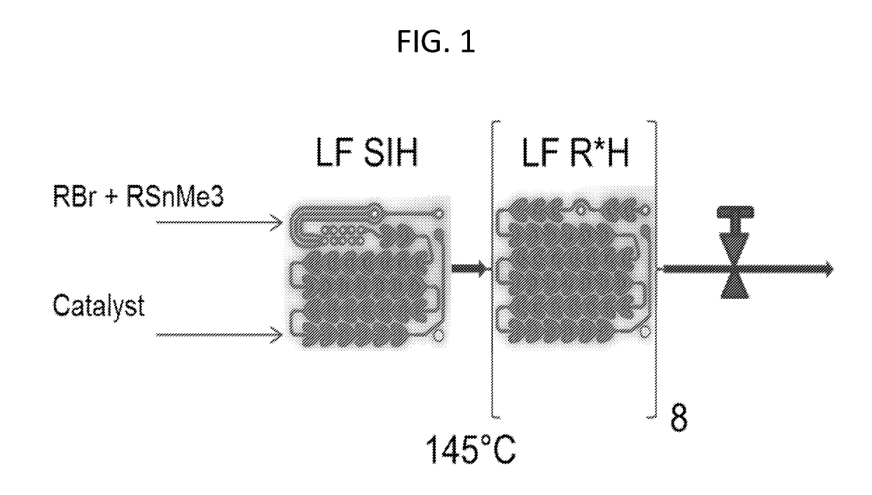

An example of a microreactor for use in the reaction process is shown in FIG. 1. Referring to the embodiment of FIG. 1, a layer 50 of a microfluidic device may comprise at least one reactant passage 60 defined within the layer 50. The reactant passage 60 may be defined by vertical wall structures, of which a cross-section is shown in the figure. As shown, multiple different reactant passages with various profiles may be used within the layer 50. Moreover, while various materials are considered suitable, the layer 50 desirably may be formed of glass, glass-ceramic, ceramic, or mixtures or combinations thereof. Other materials, such as metal or polymer, may also be used if desired.

Referring again to FIG. 1, each reactant passage 60 may comprise one or more chambers 70, 75 disposed along a central axis 110. In some embodiments, as shown in the figure a reactant passage 60 may comprise multiple chambers 70, 75 arranged in succession. As used herein, “in succession” with respect to arrangement of multiple chambers means that a chamber outlet (described below) of a first chamber 70 is in fluid communication with a chamber inlet (described below) of a second chamber 75. Though FIG. 1 depicts two chambers 70, 75 in succession, it is contemplated to use only one chamber (not shown) or more than two chambers, such as in passage 60a. Though two chambers are depicted in the figure, it should be understood that a reactant passage according to embodiments of the present disclosure need not be limited to four chambers.

Referring again to FIG. 1, in some embodiments a reactant passage 60 may comprise at least one feed inlet 90, 92, through which fluids are introduced into the reactant passage 60 to be mixed as they flow through chambers 70 and 75. Moreover, the reactant passage 60 may comprise at least one product outlet 94, through which mixed fluids may leave the reactant passage 60. As shown in FIG. 1, the reactant passage 60 may include two inlets 90 and 92 and one outlet 94 disposed near opposite ends of the reactant passage 60; however, it is contemplated to include more or fewer inlets or outlets as well as to arrange the inlets and outlets at different locations on the reactant passage 60.

Desirably, the steps in the disclosed method are performed in multiple fluidic modules, fluidically connected in series. For example, one (or more) modules is used for each of the main steps (generation of catalyst, epoxidation, quenching). Performing the reaction under continuous-flow conditions using multiple microreactor modules allows for easy optimization of the three reaction steps by performing each step in one (or more) modules well-suited to the respective step. Using such a continuous flow system with the resulting performance achievable decreases labor requirements, minimizes process volume and safety concerns, and permits continuous manufacturing of the compound, relative to competing batch techniques. With the tight thermal and process control provided in the microfluidic flow reactor, higher temperatures may be employed for epoxidation than are normally achievable, without too severe a reduction in enantioselectivity. The high temperatures allows for high yield of epoxides in short reaction times, boosting production rates. The use of a flow system also offers the possibility of easily increasing the production scale by simply “numbering-up” the number of systems. Specifically, use of Corning's Advanced-Flow™ Low Flow Reactor modules allows for potential scale-up from the low-flow modules used experimentally herein, through the G1, G2, G3 and G4 modules for a 300-fold or greater increase in production, under sufficiently similar fluid- and thermo-dynamic conditions to maintain the productivity advantages of the disclosed methods, before (external) parallelization of the reactor would be required.

In some embodiments, the compound made by the processes described herein comprises formula (III) or formula (IV):

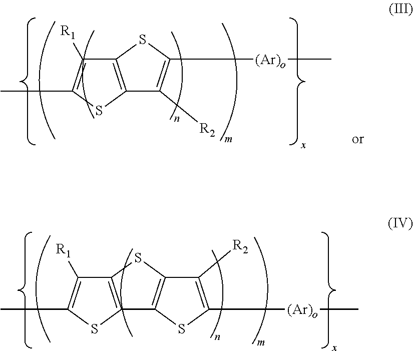

wherein R₁, R₂, m, x, and o are as described above, and Ar may be one selected from the group consisting of optionally substituted benzenes, pyrazoles, naphthalenes, anthracenes, pyrenes, thiophenes, pyrroles, thiozole, porphyrins, carbazoles, furans, indoles, and fused thiophenes.

In some embodiments, the compound made by the processes described herein comprises formula (V):

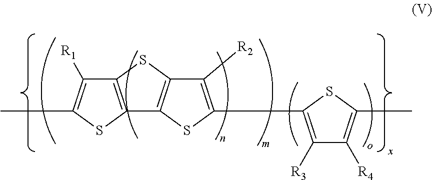

wherein R₁, R₂, n, m, x, and o are as described above.

Still another aspect comprises a method of making a compound of formula (VIII) or formula (IX):

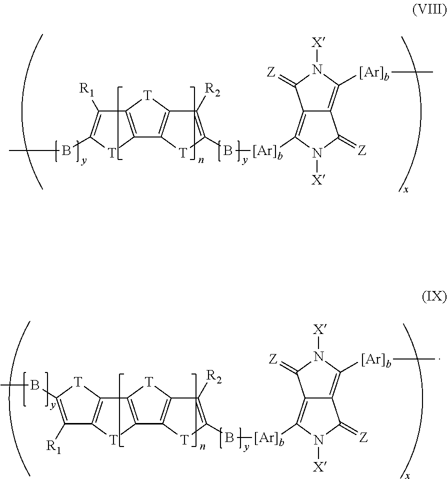

The method may include reacting a compound of formula (Xa) or formula (XIa):

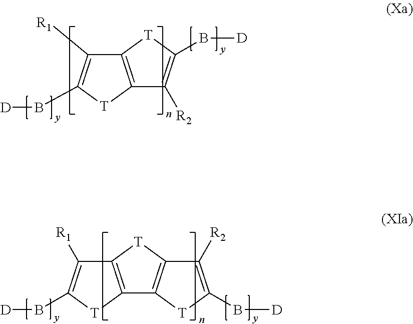

with a compound of formula (XIIa):

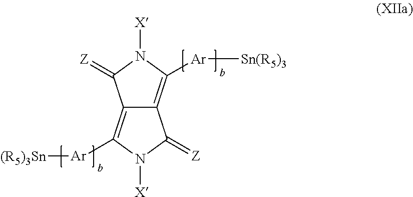

or, alternatively, reacting a compound of formula (Xb) or formula (XIb):

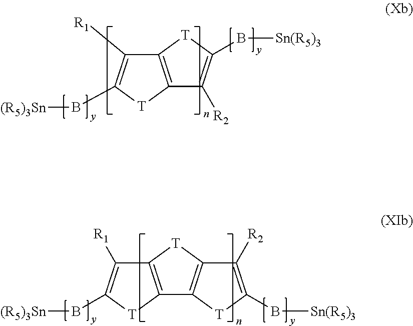

with a compound of formula (XIIb):

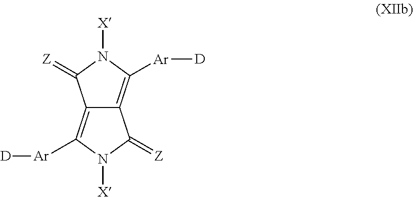

wherein the process is done in a microreactor with a metal catalyst and wherein wherein the process is done in a microreactor with a metal catalyst and wherein each T is independently S, SO, SO₂, Se, Te, BR₃, PR₃, NR₃, CR₃R₄ or SiR₃R₄, each R₃ and R₄ is independently hydrogen, substituted or unsubstituted alkyl, alkoxy, alkylthio, acylamino, acyloxy, aryloxy, substituted or unsubstituted amino, carboxyalkyl, halogen, acyl, substituted or unsubstituted thiol, aralkyl, amino, ester, aldehyde, hydroxyl, thioalkyl, acyl halide, acrylate, carboxy, or vinyl ether, substituted or unsubstituted alkenyl, each R₁ and R₂ are, independently, substituted or unsubstituted alkyl, substituted or unsubstituted alkenyl, substituted or unsubstituted cycloalkyl, substituted or unsubstituted cycloalkenyl, substituted or unsubstituted alkynyl, substituted or unsubstituted aryl, alkoxy, alkylthio, acylamino, acyloxy, aryloxy, substituted or unsubstituted amino, carboxyalkyl, halogen, acyl, substituted or unsubstituted thiol, aralkyl, amino, ester, aldehyde, hydroxyl, thioalkyl, acyl halide, acrylate, carboxy, or vinyl ether, each R₅ is independently substituted or unsubstituted alkyl, each Z may be independently be O, S, Se, or substituted imine, each D may be independently selected from the group consisting of Br, Cl, and I, each y is independently an integer from 0 to 5, each X is independently an optionally substituted C₁-C₄₀ linear or branched alkyl or heteroalkyl, or H, b may be independently less than or equal to 5 and greater than or equal to 1, each B and each Ar is independently an optionally substituted conjugated species.

In some embodiments, each b may be equal to 1. In some examples, each Z may be independently O, S, or substituted imines. In some embodiments, each Z is oxygen. In some cases, the optionally substituted conjugated species may be one selected from the group consisting of ethylene, butadiene, and acetylene. The optionally substituted aromatic species may be one selected from the group consisting of optionally substituted benzenes, pyrazoles, naphthalenes, anthracenes, pyrenes, thiophenes, pyrroles, thiozole, porphyrins, carbazoles, furans, indoles, and fused thiophenes. Each R and X′ may be independently an optionally substituted C₆-C₂₄ linear alkyl chain. In other embodiments, each R and X′ may be independently an optionally substituted C₁₃-C₁₉ linear alkyl chain. The optionally substituted alkyl chain containing heteroatoms may be one selected from the group consisting of oligo(ethylene glycol), oligo(propylene glycol), and oligo(ethylene diamine). The substituted alkyl chains may include ketone, amine, ester, one or more unsaturations, halide, nitro, aldehyde, hydroxyl, carboxylic acid, alkoxy, or any combination thereof. Each x may independently be an integer from 8 to 250. In some embodiments, B or Ar is independently selected from the group consisting of an optionally substituted alkenyl. In some embodiments, each B and Ar is independently an optionally substituted aryl. In some embodiments, each B or Ar is independently selected from the group consisting of optionally substituted benzenes, pyrazoles, naphthalenes, anthracenes, pyrenes, thiophenes, pyrroles, thiozole, porphyrins, carbazoles, furans, indoles, and fused thiophenes.

In some embodiments of the aspects above, the metal catalyst may be selected from the group consisting of Pt, Pd, Ru, and Rh.

As described above, embodiments describe a series of synthetic steps. However, the methods disclosed herein are intended for purposes of exemplifying only and are not to be construed as limitations thereon. Those skilled in the art will appreciate that additional and/or other synthetic steps may be used or necessary in the synthesis of the compounds described herein. Some aspects of some embodiments may be synthesized by synthetic routes that include processes analogous to those well-known in the chemical arts, particularly in light of the description contained herein. Although specific starting materials and reagents are depicted in the schemes and discussion herein, other starting materials and reagents can be easily substituted to provide a variety of derivatives and/or reaction conditions. The starting materials are generally available from commercial sources, such as Aldrich Chemicals (Milwaukee, Wis.), or are readily prepared using methods well known to those skilled in the art (e.g., prepared by methods generally described in Louis F. Fieser and Mary Fieser, REAGENTS FOR ORGANIC SYNTHESIS, v. 1-19, Wiley, New York (1967-1999 ed.), or BEILSIEINS HANDBUCH DER ORGANISCHEN CHEMIE, 4, Aufl. ed. Springer-Verlag, Berlin, including supplements (also available via the Beilstein online database)). In addition, many of the compounds prepared by the methods described below can be further modified in light of this disclosure using conventional chemistry well known to those skilled in the art.

For example, precursors for the formation of the starting materials described herein may be made via conventional processes or alternatively, via microreactor-based processes. Examples of methods for forming starting materials are illustrated in Scheme 1 depicted below such that the product of Scheme 2 depicted below may be synthesized.

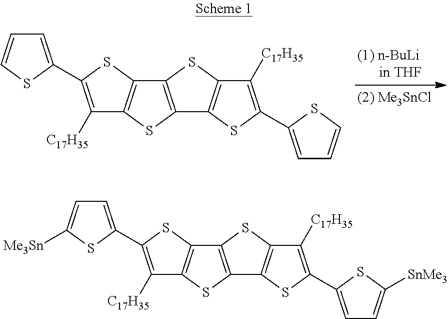

### Examples

Example 1 (prospective)—A prospective example of a method included herein is the synthesis described in Schemes 2 and 3 wherein the synthesis is done in a microreactor. In either case, n may be in a range of 1 to 200 or, for example, 1 to 50. For Scheme 3, each R is equivalent to R₁, Ar is as defined herein, and Me is methyl.

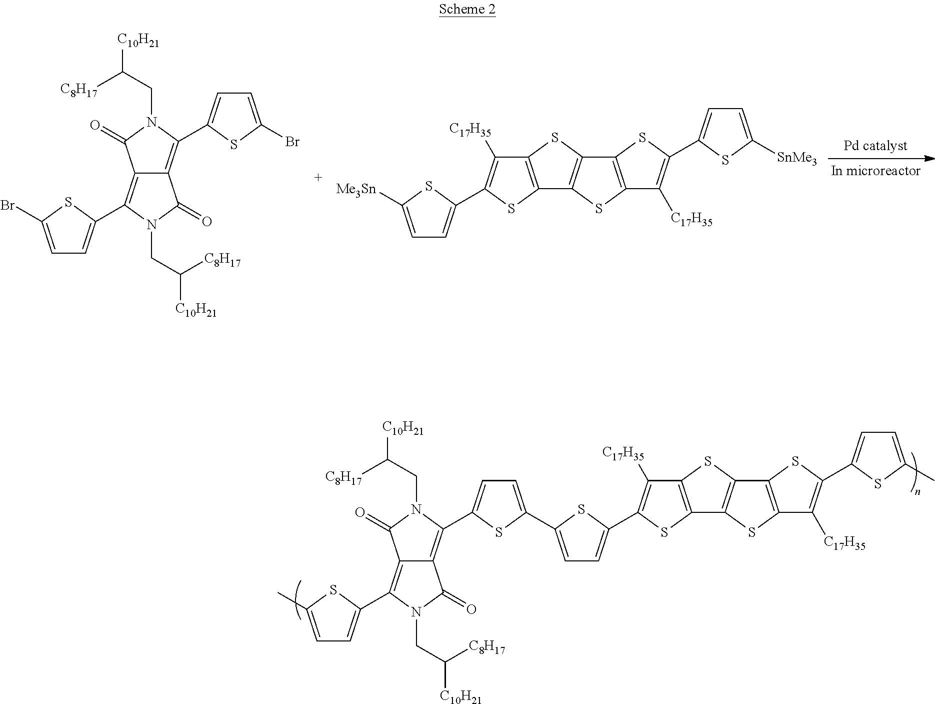

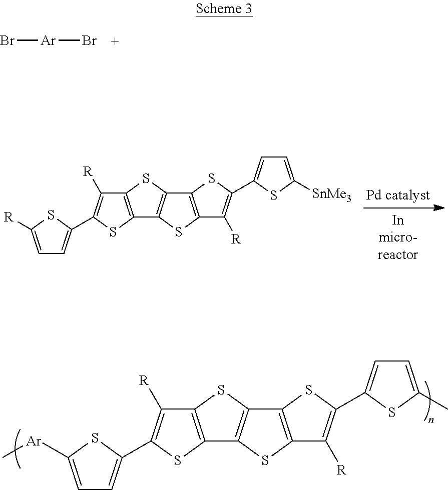

Example 2—Scheme 4 is an example of a synthesis done via the embodied processes described herein.

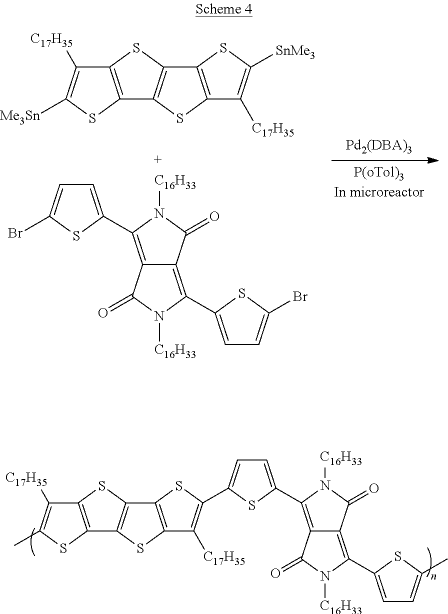

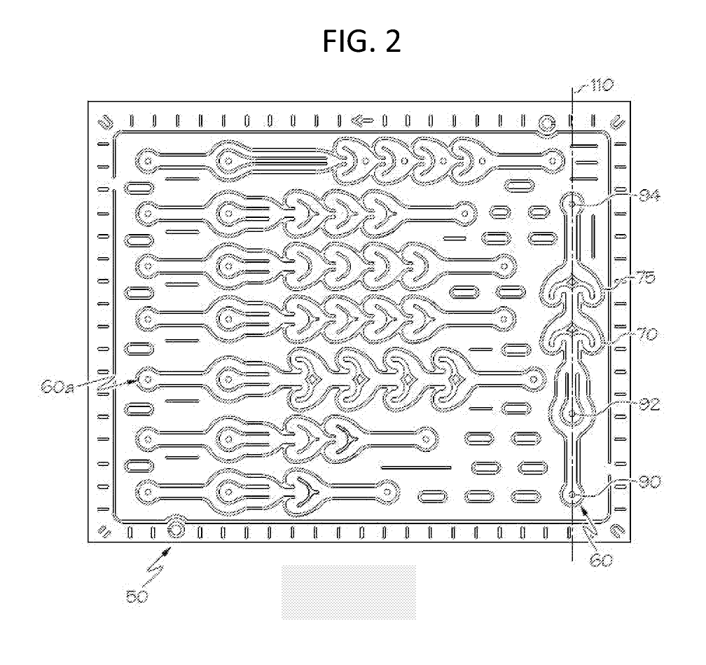

The microreactor setup comprises the following design: two solutions were pumped using a dosing lines made out of micro gear pumps (HNP mzr 7205) and mass flow controllers (Bronkhorst Coriolis mass flow controller M13). The solutions are kept under argon at all times. The reactor itself is an Advanced-Flow™ Low Flow Reactor composed out of a mixing module type LF SH and 8 residence time modules type LF R*H (FIG. 2). At the reactor exit is a backpressure regulator utilized in order to increase the reaction temperature above boiling point. The reactor is dried before use by rinsing with ethanol for 2 hours. After 2 hours, the ethanol is replaced by heptane, which is replaced by toluene just prior to the experiment.

In order to aid in keeping the stoichiometric ratio between tin-FT4 and bromothienyl-DPP as close to 1:1 as possible, the two monomers are weighed into the same reservoir vessel and dissolved into chlorobenzene (toluene may also be used instead of chlorobenzene). The palladium pre-catalyst and additional phosphine ligands are dissolved into the same solvent in a separate reservoir vessel. The two solutions are carefully degassed with argon. In order to maintain these monomers in solution, it is necessary to pre-heat the combined monomers solution prior to introduction to the microreactor. The mixture is pre-heated to 60° C. to insure full dissolution and the maintenance of a solid free solution—necessary in order to maintain the stoichiometric monomer ratio and to prevent clogs in the pumps and tubing leading to the microreactor reaction plates. The monomer and catalyst feeds are then pumped at appropriate relative rates to give a 4 mol % ratio of single palladium species to monomers in the microreactor while the microreactor temperature is maintained at 160° C. The reaction is self-indicating, in that the mixed monomers are a bright pink color at temperature while the polymer is blue at low molecular weights and a dark green once full molecular weight is achieved. In this experiment material is collected from the outflow of the microreactor into an empty collection vessel and the polymer is then precipitated. However, the outflow could easily be dripped into a stirring solution of a non-solvent for the polymer that is miscible with the reaction solvent in order to induce precipitation of the polymer while solvating the residual catalyst species. Methanol mixed with acetylacetone may be used for this purpose.

It will be apparent to those skilled in the art that various modifications and variations can be made to the present invention without departing from the spirit and scope of the invention. Thus, it is intended that the present invention cover the modifications and variations of this invention provided they come within the scope of the appended claims and their equivalents.

What is claimed is:

1. A process comprising the making a compound of formula (I) or formula (II): 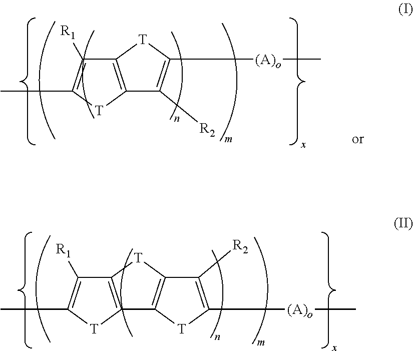
by reacting a compound of formula (Ia) or (IIa): 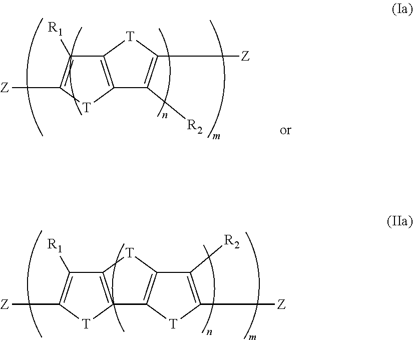
with a compound having the formula:
(R₅)₃Sn-A-Sn(R₅)₃
or by reacting a compound of formula (Ib) or (IIb): 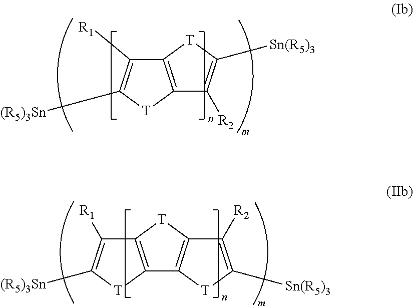
with a compound having the formula:
Z-A-Z
wherein the process is done in a microreactor with a metal catalyst and wherein each T is independently S, SO, SO₂, Se, Te, BR₃, PR₃, NR₃, CR₃R₄ or SiR₃R₄, each R₃ and R₄ is independently hydrogen, substituted or unsubstituted alkyl, alkoxy, alkylthio, acylamino, acyloxy, aryloxy, substituted or unsubstituted amino, carboxyalkyl, halogen, acyl, substituted or unsubstituted thiol, aralkyl, amino, ester, aldehyde, hydroxyl, thioalkyl, acyl halide, acrylate, carboxy, or vinyl ether, substituted or unsubstituted alkenyl, each R₁ and R₂ are, independently, substituted or unsubstituted alkyl, substituted or unsubstituted alkenyl, substituted or unsubstituted cycloalkyl, substituted or unsubstituted cycloalkenyl, substituted or unsubstituted alkynyl, substituted or unsubstituted aryl, alkoxy, alkylthio, acylamino, acyloxy, aryloxy, substituted or unsubstituted amino, carboxyalkyl, halogen, acyl, substituted or unsubstituted thiol, aralkyl, amino, ester, aldehyde, hydroxyl, thioalkyl, acyl halide, acrylate, carboxy, or vinyl ether, each R₅ is independently substituted or unsubstituted alkyl, each Z is independently Cl, Br, or I, n is an integer of 1 or more, x, m and o are independently integers of 1 or more, and each A is independently a conjugated group.

2. The process of claim 1, wherein x is an integer from about 10 to about 200.

3. The process of claim 1 or claim 2, wherein o is an integer from 1 to 5, and m is an integer from 1 to 5.

4. The process of any of claims 1-3, wherein A is selected from the group consisting of an optionally substituted alkenyl.

5. The process of any of claims 1-3, wherein A is an optionally substituted aryl.

6. The process of claim 5, wherein A is selected from the group consisting of optionally substituted benzenes, pyrazoles, naphthalenes, anthracenes, pyrenes, thiophenes, pyrroles, thiozole, porphyrins, carbazoles, furans, indoles, and fused thiophenes.

7. The process of claim 1, wherein, the compound made by the processes described herein comprises formula (III) or formula (IV): 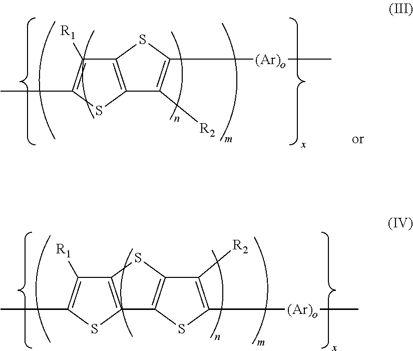
wherein Ar may be one selected from the group consisting of optionally-substituted benzene, pyrazole, naphthalene, anthracene, pyrene, thiophene, pyrrole, thiozole, porphyrin, carbazole, furans, indoles, and fused thiophene.

8. The process of claim 7, wherein the compound made by the processes described herein comprises formula (V): 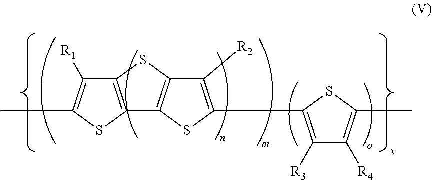
wherein R₁, R₂, R₃, R₄, n, m, x, and o are as defined in claim 1.

9. A process of making a compound of formula (VIII) or formula (IX): 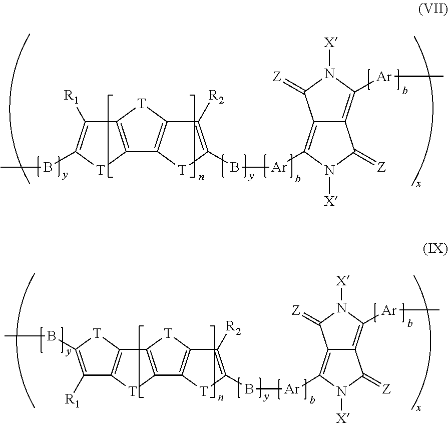
comprising reacting a compound of formula (Xa) or formula (XIa): 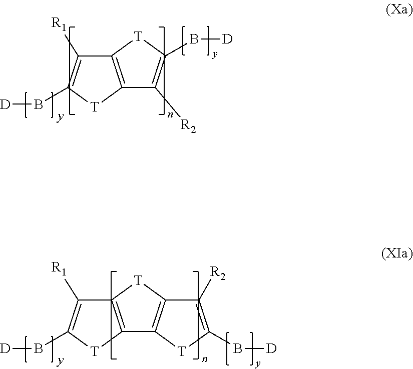
with a compound of formula (XIIa): 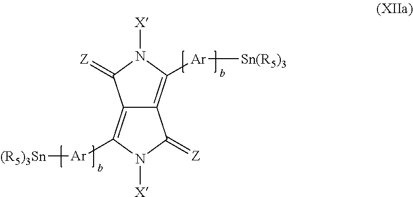
or, alternatively, reacting a compound of formula (Xb) or formula (XIb): 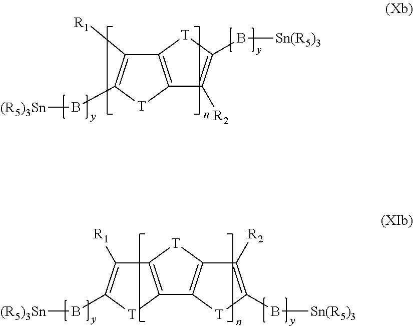
with a compound of formula (XIIb): 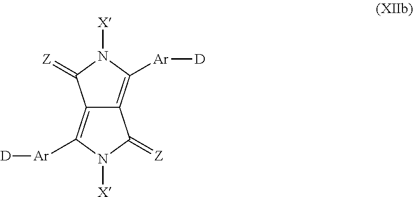
wherein the process is done in a microreactor with a metal catalyst and wherein each T is independently S, SO, SO₂, Se, Te, BR₃, PR₃, NR₃, CR₃R₄ or SiR₃R₄, each R₃ and R₄ is independently hydrogen, substituted or unsubstituted alkyl, alkoxy, alkylthio, acylamino, acyloxy, aryloxy, substituted or unsubstituted amino, carboxyalkyl, halogen, acyl, substituted or unsubstituted thiol, aralkyl, amino, ester, aldehyde, hydroxyl, thioalkyl, acyl halide, acrylate, carboxy, or vinyl ether, substituted or unsubstituted alkenyl, each R₁ and R₂ are, independently, substituted or unsubstituted alkyl, substituted or unsubstituted alkenyl, substituted or unsubstituted cycloalkyl, substituted or unsubstituted cycloalkenyl, substituted or unsubstituted alkynyl, substituted or unsubstituted aryl, alkoxy, alkylthio, acylamino, acyloxy, aryloxy, substituted or unsubstituted amino, carboxyalkyl, halogen, acyl, substituted or unsubstituted thiol, aralkyl, amino, ester, aldehyde, hydroxyl, thioalkyl, acyl halide, acrylate, carboxy, or vinyl ether, each R₅ is independently substituted or unsubstituted alkyl, each Z may be independently be O, S, Se, or substituted imine, each D may be independently selected from the group consisting of Br, Cl, and I, each y is independently an integer from 0 to 5, each X′ is independently an optionally substituted C₁-C₄₀ linear or branched alkyl or heteroalkyl, or H, b may be independently less than or equal to 5 and greater than or equal to 1, each B and each Ar is independently an optionally substituted conjugated species.

10. The process of claim 9, wherein each b is 1.

11. The process of claim 9 or claim 10, wherein each Z may be independently O, S, or a substituted imine.

12. The process of claim 11, wherein Z is oxygen.

13. The process of any of claims 9-12, wherein B or Ar is selected from the group consisting of an optionally substituted alkenyl.

14. The process of any of claims 9-12, wherein B or Ar is an optionally substituted aryl.

15. The process of claim 14, wherein B or Ar is selected from the group consisting of optionally substituted benzenes, pyrazoles, naphthalenes, anthracenes, pyrenes, thiophenes, pyrroles, thiozole, porphyrins, carbazoles, furans, indoles, and fused thiophenes.

16. The process of any of claims 9-12, wherein each R₁, R₂, R₅ and X′ may be independently an optionally substituted C₆-C₂₄ linear alkyl chain wherein the optionally substituted alkyl chain may contain heteroatoms selected from the group consisting of oligo(ethylene glycol), oligo(propylene glycol), and oligo(ethylene diamine), or may include ketone, amine, ester, one or more unsaturations, halide, nitro, aldehyde, hydroxyl, carboxylic acid, alkoxy, or any combination thereof.

17. The process of claim 16, wherein each R₁, R₂, R₅ and X′ may be independently an optionally substituted C₁₃-C₁₉ linear alkyl chain.

18. The process of any of claims 9-17, wherein each x is from about 10 to about 200.

19. The process of any of claims 1-18, wherein the metal catalyst may be selected from the group consisting of Pt, Pd, Ru, and Rh.

20. The process of any of claims 1-19, wherein the microreactor comprises a continuous-flow microreactor.

21. The process of claim 20, wherein the microreactor comprises a microchannel-based microreactor.

22. The process of claim 20, wherein the microreactor comprises one or more heat exchange channels.
